(19) United States
(12) Patent Application Publication
(10) Pub. No.: US 2002/0181714 A1
(43) Pub. Date: Dec. 5, 2002

(54) Audio processing, e.g. for discouraging vocalisation or the production of complex sounds

(76) Inventor: Graeme John Proudler, Bristol (GB)

Correspondence Address: Angus C Fox III, 4501 North Windsor Drive, Provo, UT, 84604-6303, US

(21) Appl. No.: 10/149,893

(22) PCT Filed: Dec. 4, 2000
(86) PCT No.: PCT/GB00/04645

(30) Foreign Application Priority Data
Dec. 15, 1999 (GB) 9929519.8

(51) Int. Cl. H04R 29/00; H03G 3/20

(52) U.S. Cl. 381/57; 381/56

(57) ABSTRACT

An audio processing method and apparatus are described for discouraging vocalization or the production of complex sounds. The method comprises the steps, performed in a repeating cycle, of: receiving (74) ambient audio; detecting (74) when the received ambient audio is loud; and broadcasting (84, 92) a burst of output audio so as to mix with the ambient audio, the burst of output audio being timed in dependence upon the detection of loud ambient audio.

### DESCRIPTION

This invention relates to audio processing methods and apparatus, particularly (but not exclusively) for use in discouraging vocalisation or the production of complex sounds.

In this invention, the term ‘vocalisation’ includes not only speech but also other sounds uttered by both human beings and also animals, and the term ‘complex sounds’ includes other sounds and noises such as music whether generated live or being a replay of a recording. The term ‘ambient audio’ implies an ensemble of sounds in a volume, which are not necessarily produced for the purpose of detection by a sensor, and whose sources are not necessarily in close physical proximity to such a sensor. This is in contrast to localised audio, which implies sounds (perhaps just one specific sound) that may be produced for the express purpose of detection by a sensor, whose sources may be in close physical proximity to the sensor. Detection of ambient audio generally requires much greater amplifier sensitivity than detection of localised audio.

Often vocalisation or other complex sounds are unwelcome. Situations may occur, for example, during the course of employment involving contact with members of the public, or control of unruly individuals. An employee, for example at a social security office or a football ground turnstile or a railway station, may feel threatened by vocalisation, or be required to regain control of a situation but be unable or unwilling to apply direct force. Such threatening situations reduce the effectiveness of the employee and can cause job-related stress. It is therefore desirable to provide support for employees in such situations. There are presently few if any methods of providing such assistance: the employee must wait out the situation or try to verbally interrupt the unwanted vocalisation.

The present invention is concerned with discouraging such vocalisation and/or production of other ambient audio. Some methods described herein may be said to ‘interfere’ with undesirable spoken words, since they produce ambient audio at the same time as the undesirable spoken words. Other methods may be said to ‘interrupt’ a speaker, since they reflect spoken words back to the speaker just after the end of an undesirable word, in the same way that a person would normally interrupt another person.

Some patent publications which relate to the same or similar fields include:

U.S. Pat. No. 3,673,567 (McClellan) “Remote dog-bark suppressor” describes a method of silencing dogs by mimicry. It mentions the problem of regenerative feedback, from speaker to microphone.

U.S. Pat. No. 3,823,691 (Morgan) “Animal training device” discloses a device for preventing vocalisation of animals, particularly dogs. The emphasis is on the detection of ambient audio to control production of output audio, which is a frequency shifted version of the dog's bark. The device detects the presence of input audio, and deactivates the output audio when there is no input audio. The output may be delayed.

U.S. Pat. No. 4,202,293 (Gonda) “Dog training collars and methods” discloses a device for preventing vocalisation of animals, particularly dogs. The device detects input audio and uses it to activate a buzzer. After the buzzer has been activated for a preset time, the buzzer is disabled for a preset time.

U.S. Pat. No. 4,464,119 (Vildgrube) “Method and device for controlling speech” discloses an invention for preventing stammering. The device permits a person to hear a delayed version of his own voice. The delay may be adjusted. Input audio is detected and used to activate the output.

U.S. Pat. No. 5,749,324 (Moore) “Apparatus and methods for controlling animal behaviour” discloses a device for preventing vocalisation of animals, particularly dogs. The emphasis is on recognising sounds, and producing a stimulus as a result of recognising those sounds. Those sounds are animal noises (barking) and words spoken by humans. The device can correlate animal noises with human spoken words, and cause an output noise to be made in response.

In accordance with the present invention, there is provided an audio processing method, for example for discouraging vocalisation or the production of complex sounds, the method comprising the steps, performed in a repeating cycle, of: receiving ambient audio; detecting when the received ambient audio is loud; and broadcasting a burst of output audio so as to mix with the ambient audio, the burst of output audio being timed in dependence upon the detection of loud ambient audio. The method is particularly, but not exclusively, intended to be used in circumstances in which the ambient audio (at least at the point of reception) is relatively quiet and yet the output audio is relatively loud.

The production of output audio may be dependent upon some or all of the following methods and events:

inspecting desirable ambient audio to determine the characteristics of desirable audio that distinguish loud and quiet desirable audio;

determining the presence and/or absence of loud desirable ambient audio;

the presence of quiet desirable ambient audio;

the presence of loud desirable ambient audio;

inspecting undesirable ambient audio to determine the characteristics of undesirable audio that distinguish loud and quiet undesirable audio;

determining the presence and/or absence of loud undesirable ambient audio;

the presence of quiet undesirable ambient audio;

the presence of loud undesirable ambient audio;

inspecting ambient audio to determine the characteristics of ambient audio that distinguish new ambient audio from echoes of previous output audio;

determining the presence and/or absence of new ambient audio that dominates echoes of previous output audio;

the presence of new desirable ambient audio that dominates echoes of previous output audio;

the presence of new undesirable ambient audio that dominates echoes of previous output audio;

the number of previous events of production of output audio.

In particular, the method preferably further comprises the step, in each cycle, of deciding whether or not to perform the broadcasting step in dependence upon at least one parameter related to the received ambient audio and/or the broadcast output audio.

In the deciding step, the decision may be made in dependence upon the length of time for which the received ambient audio is loud. For example, the decision may be made not to perform the broadcasting step if the received ambient audio is loud for less than a first predetermined period of time. This can assist in preventing mistriggering of output audio in response to an extraneous transient noise. Additionally or alternatively, in the deciding step, the decision may be made in dependence upon the length of time since the preceding broadcast of such a burst of output audio. For example, the decision may be made not to perform the broadcasting step if the length of time since the preceding broadcast of such a burst of output audio is less than a second predetermined period of time. This can assist in preventing mistriggering in response to an echo of previous output audio. In these cases, the decision may be made to perform the broadcasting step if the received ambient audio is loud for more than said first predetermined period of time and the length of time since the preceding broadcast of such a burst of output audio is more than said second predetermined period of time. Additionally or alternatively, the decision may be made to perform the broadcasting step if the received ambient audio is loud for more than a third predetermined period of time. This can assist in preventing the method locking up.

Preferably, the method further comprises the step of ignoring any detection of loud ambient audio for a period of time after the broadcasting step, for example a fourth predetermined period of time. This can also assist in preventing mistriggering in response to an echo of previous output audio.

The broadcasting step may be commenced immediately that loud ambient audio is detected. However, in each cycle, there is preferably a delay between the time when the ambient audio is detected as loud and the time when the broadcasting step is commenced. During the delay, the ambient audio can be assessed to determine whether it should trigger output audio, and in some embodiments can be processed in order to generate the output audio. For example, in the case where the ambient audio is detected as loud for less than a fifth predetermined period of time, the broadcasting step may be commenced substantially immediately that the ambient audio ceases to be detected as loud, and in the case where the ambient audio is detected as loud for said fifth predetermined period of time, the broadcasting step may be commenced substantially immediately at the end of said fifth predetermined period of time. Accordingly, a short burst of ambient audio will trigger a burst of output audio immediately after the burst of ambient audio, whereas a long burst of ambient audio will trigger a burst of output audio a predetermined time after the start of the burst of ambient audio or after the start of the cycle.

Preferably, the method further comprises the step of making one of the following decisions:

whether or not the received incident audio is loud at substantially the beginning of each cycle;

whether or not incident audio has been predominantly loud for a given time; or

whether or not a predetermined number of output cycles have already occurred, and selecting between a first mode of operation if it is (an ‘interfering’ mode), and a second mode of operation if it is not (an ‘interrupting mode’). In this case, the period of time for which the output audio is broadcast may be determined differently in the two modes. Additionally or alternatively, said fifth predetermined period of time (mentioned above) is preferably different in the two modes, so as, in general, to achieve the interrupting effect and the interfering effect.

The method may further comprise the step, in each cycle, of generating the output audio at least in part from the received ambient audio. In this case, the method preferably includes the step of automatically controlling the level of the output audio, for example by detecting the level of the received audio, and applying a gain in generating the output audio dependent on the detected level so that the peak level of each burst of output audio is substantially predetermined. In this case, in the level detecting step, the level of the received audio is preferably ignored while each broadcasting step is being performed, and preferably also for a period of time immediately after each broadcasting step has been performed. It may also be conditionally ignored for a first period of time or temporarily ignored for a second period of time. The content of the output audio may be produced at least in part from the substantially current content of the received ambient audio or at least in part from delayed content of the received ambient audio.

Alternatively or additionally, the content of the output audio may be produced at least in part from a source independent of the incident ambient audio, such as a white noise generator, a coloured-noise generator, or an oscillatory-signal generator.

The step of detecting loud ambient audio preferably comprises comparing the level of the received audio with at least one threshold. In this case, the method preferably further comprises the step of automatically adjusting the threshold, or at least one of the thresholds, in dependence upon an average value of the level of the received ambient audio. Preferably, adjustment of the threshold(s) is independent of the level of the received ambient audio while each broadcasting step is being performed, and preferably also for a period of time immediately after each broadcasting step has been performed. It may also be conditional for a first period of time or be temporarily delayed for a second period of time.

Determining the presence and/or absence of loud ambient audio may involve some or all of the following: ignoring bursts of loud ambient audio that are shorter than typical spoken words; setting agc and/or threshold detection levels, not altering agc and/or threshold detection levels while broadcasting output audio, not altering agc and/or threshold detection levels for a first time after broadcasting output audio, conditionally adapting agc and/or threshold detection levels for a second time after broadcasting output audio; not adapting threshold detection levels with data obtained between the said first time and a second time until the said second time; ignoring incident ambient audio while broadcasting output audio, ignoring ambient audio for a first time after broadcasting output audio, conditionally ignoring incident audio for a second time after broadcasting output audio, where the second time is longer than the first time.

The previous methods may be combined with a further method, such that desired audio may be broadcast instead of output audio produced according to the previous methods. This has the effect of providing a conventional loud hailer when desired audio is detected.

The invention also provides an audio processing apparatus adapted to perform the method described above.

A main objective of an embodiment of the present invention is the prevention of recognition of broadcast output audio as new ambient audio from a desirable or undesirable source. An apparatus that mistriggers in such a way is likely to oscillate and may be ineffective at responding to original input audio. Another objective is the obstruction of offensive human speech. This has three further main implications. First, that the timing attributes of the apparatus are preferably matched to the characteristic timings of human speech, in order that apparatus is able to respond to a spoken word in time to obstruct that spoken word. Second, that deadtime is preferably minimised. In this context, deadtime is a period or periods where apparatus does not respond to a spoken word and (obviously) fails to obstruct that spoken word. Any significant deadtime obviously enables offensive words to be spoken during that deadtime, and significantly reduces the effectiveness of the invention. Third, that the apparatus preferably mimics the response of a human. In this context, undesirable spoken words should be interfered with when it is desired to be more assertive, such as when production of undesirable audio fails to stop. Undesirable spoken words should be interrupted when it is desired to be less assertive, such as when production of undesirable audio is infrequent. These four objectives have significant impact on the present invention.

Mistriggering can be prevented if the characteristics of broadcast output audio are not those that are used to recognise input audio. This is possible if output signals use frequencies that are not detected in input signals, or if a device can recognise sounds, and input sounds are different from output sounds, for example.

Mistriggering can also be prevented when the characteristics of broadcast output audio are those that are recognised as input audio. There are several ways that such mistriggering might be prevented. Generally, in order for mistriggering to occur the audio input should detect the audio output. This requires (1) that there is sufficient loop gain from the output actuator to the input detector and (2) that the input detector is enabled when there is sufficient loop gain from the output actuator to the input detector and output audio is present. It must be appreciated that ambient audio derived from output audio can still be present in the form of echoes after active production of output audio has ceased. Such echoes may be similar in strength to that of original ambient audio, but may be psychoacoustically overwhelmed by original ambient audio. It must also be appreciated that threshold parameters and agc parameters may be distorted if the input detector is searching for distant (weak) sounds, but is exposed to local (strong) sounds when output audio is produced.

The first requirement depends on the volume of the output audio, the physical position of the audio sensor relative to the audio output actuator, and the amount of amplification in the audio input. The second requirement depends on various timing elements.

A first approach to maintaining stability would be to use an output stage that is responsive to output audio, without an input stage that is responsive to output audio. Such a device will typically have several timing elements, including:

The input stage can have a “sensitivity time constant”, such that loud signals whose duration is less than the sensitivity time constant are rejected. This is provided to eliminate mistriggering caused by arbitrary inoffensive noises.

The apparatus can have an “activation-hold time constant”, which determines the length of time for which the apparatus input remains in the active state, after a loud sound that is longer than the sensitivity time constant has been detected.

The output stage can have a “disable time constant”, which is the time for which the audio output is disabled, at the end of a period where the audio output has been active.

Clearly, different combinations and values of time constants produce devices with different characteristics, some of which are stable and some of which are not. A number of compromises may be required. Stability may require a sensitivity time constant that is longer than echoes of output audio, in order that echoes are not detected, but a very long sensitivity time constant may prevent desired detection of original ambient audio. Stability may require an activation-hold time constant that is shorter than the disable time constant, in order that active output audio does not cause reactivation, but a short activation-hold time constant may cause inappropriate detection of the end of original ambient audio. Stability may require a disable time constant that is longer than the duration of echoes plus the activation-hold time constant, in order that active output audio does not cause reactivation, but the disable time constant is pure dead time, where the apparatus is unable to respond to original ambient audio. The less the physical isolation of the audio sensor from the output actuator and the more acoustically sensitive the input stage, the worse the compromises become. Further, if original input audio is present at the end of active output audio, it may not be necessary or even desirable to ignore the audio input. The compromises may be further worsened if the apparatus uses inaccurate timings, such as those provided by analogue circuitry.

This first approach (an output stage that is responsive to output audio, without an input stage that is responsive to output audio) has other limitations: threshold parameters and agc parameters may be distorted if the input adapts to local (strong) sounds when output audio is produced, but normally is adapted to distant (weak) sounds. In such cases, the apparatus may respond in an undesirable fashion (or not respond at all) for a period after the output of audio.

This first approach is not well suited to the objectives of the present invention and is therefore preferably not used. There are a number of design compromises, there is inevitable dead time, it is incompatible with quiet inputs and loud outputs, and it does not cope with original ambient audio during echoes. Apparatus according to this first approach may be less than fully successful in responding to offensive human speech.

A second approach to maintaining stability (used in the present invention) has an input stage that is responsive to output audio, without an output stage that is responsive to output audio. This approach decouples the constraints on time constants, practically eliminates deadtime, enables acoustic sensitivity and detection while permitting loud output audio, and can cope with original ambient audio during echoes. This enables greater design freedom to meet the timing requirements of human speech.

Specific embodiments of the present invention will now be described, purely by way of example, with reference to the accompanying diagrams, in which:

FIG. 1 schematically illustrates the relationship between the input ambient audio and the output broadcast audio according to the present invention;

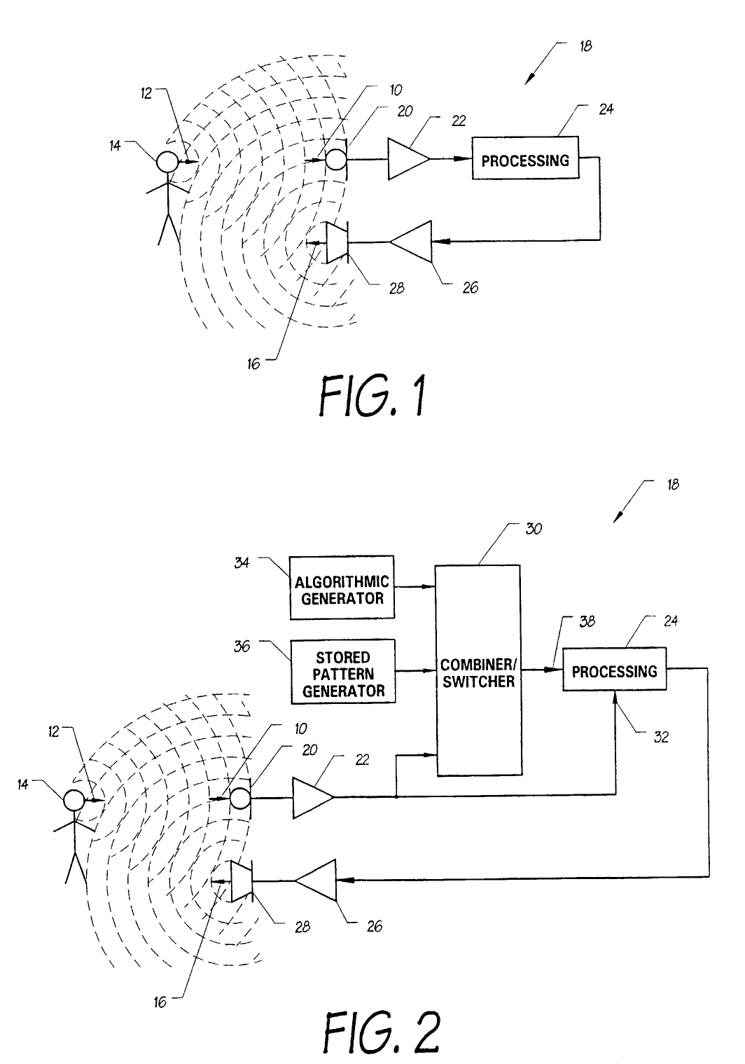

FIG. 2 schematically illustrates a first example of a method according to the present invention;

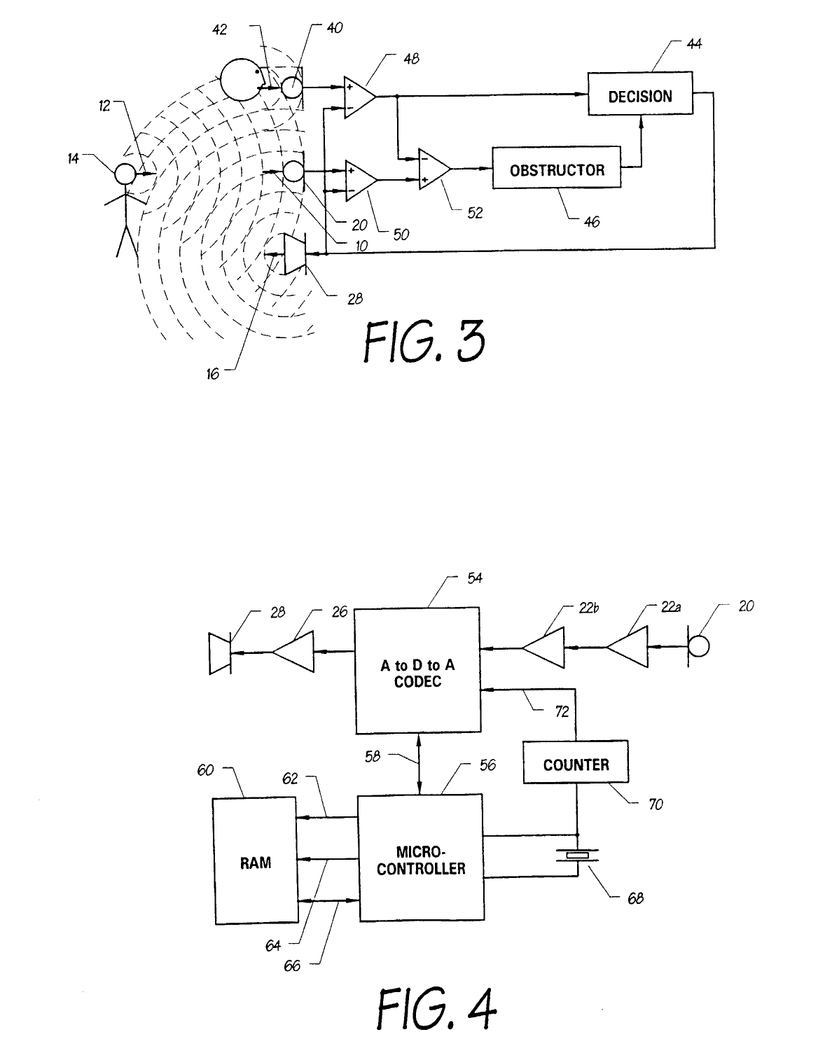

FIG. 3 schematically illustrates a second example of a method according to the present invention;

FIG. 4 is a block diagram of an apparatus for performing the first example;

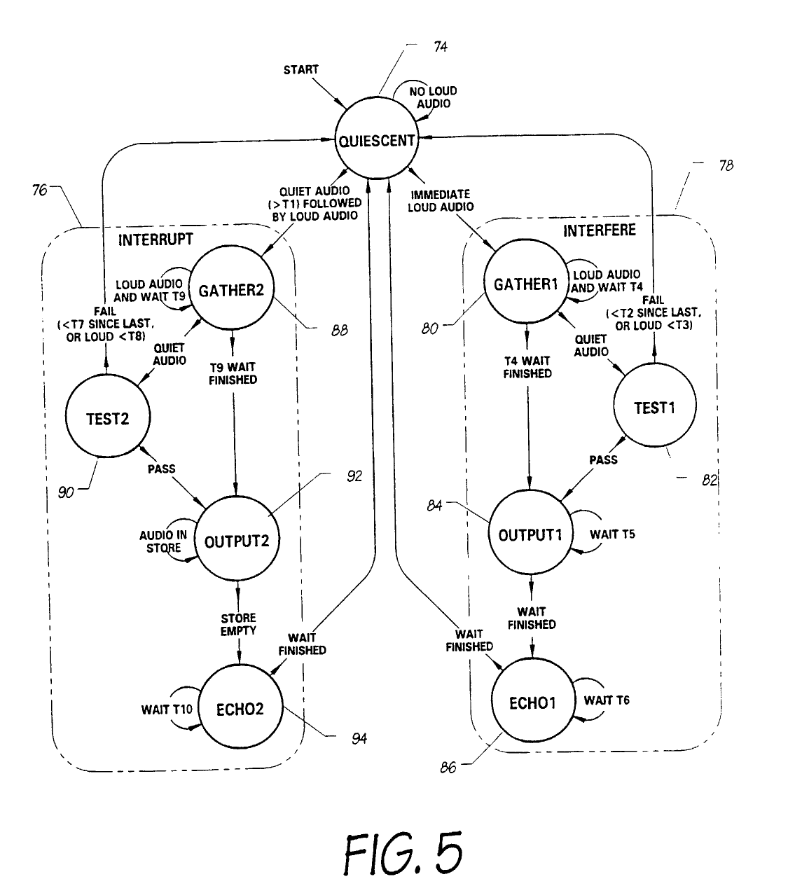

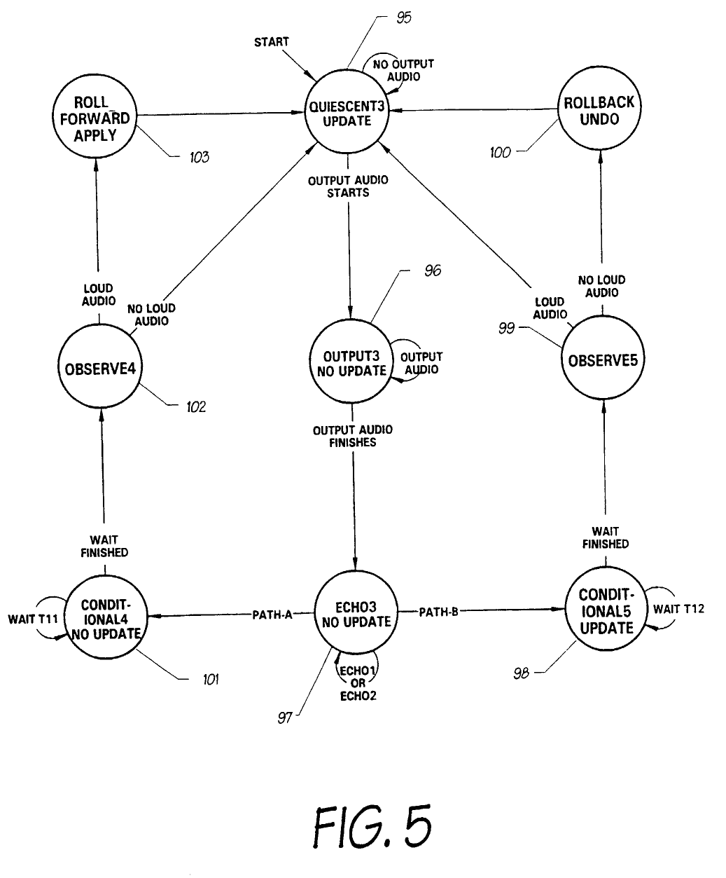

FIG. 5 is a state diagram to illustrate the operation of the apparatus of FIG. 4; and

FIG. 6 is a second state diagram to illustrate the operation of the apparatus of FIG. 4.

FIG. 1 illustrates the relationship between the ambient audio 10, the audio 12 from an undesirable source 14, and the broadcast output audio 16 produced by an apparatus 18. The ambient audio 10 is converted by microphone 20 into a signal that is amplified to usable levels by preamplifier 22. The signal is processed by a processing block 24, which produces an output signal that is amplified by a power amplifier 26 and broadcast by loudspeaker 28. The broadcast audio 16 mixes with audio 12 from the undesirable source 14 to form the ambient audio 10.

The undesirable source 14 is typically relatively distant from the apparatus 18, because of the difficulty and possible hazard of positioning the apparatus 18 close to the source 14 of undesirable audio 12. The signal produced by microphone 20 from the undesirable component of the ambient audio 10 is therefore of relatively small size, and requires significant amplification by preamplifier 22 to reach a usable level. The actual distance between the apparatus 18 and the source 14 of undesirable audio 12 is generally unpredictable, and the size of the undesirable audio is generally unpredictable. If the processing block 24 uses undesirable input audio as a component of output audio 16, processing block 24 applies variable amounts of amplification to its input signal to produce a component of consistent peak or average amplitude. Such agc methods are well known to those skilled in the art of audio processing. Processing block 24 also uses its input signal to derive an adaptive threshold in order to distinguish between loud undesirable input audio and silence. Such methods are well known to those skilled in the art of audio processing, and may be combined with methods of age control. The broadcast audio 16 produced by loudspeaker 28 must be relatively loud in order to carry to the distant source 14 of undesirable audio 12 and disrupt the undesirable audio 12 at that source 14. Since the microphone 20 is normally adjacent the loudspeaker 28, the size of the audio input to processing block 24 caused by broadcast output ambient audio is generally significantly larger than that caused by undesirable ambient audio. Such a difference can significantly disturb the agc and threshold parameters of processing block 24, such that undesirable audio is not properly detected for a time after the production of broadcast output audio, until the agc and threshold parameters readjust. It may therefore be desirable to disable changes to the agc and threshold parameters of processing block 24 during the production of broadcast output audio, in order to minimise deadtime after the production of broadcast output audio. Methods to perform such disabling are well known to those skilled in the art of audio processing, and may include holding constant the voltage on a capacitor or locking the contents of digital memory, for example. As will be described later, it may also be desirable to disable changes to the agc and threshold parameters of processing block 24 for a period after the production of broadcast output audio 16, because echoes of broadcast output audio are present after the apparatus ceases to actively broadcast output audio. The agc parameters and threshold parameters may be frozen and also conditionally accepted until retrospectively rolled-back at the end of the echo period. The threshold parameters may also be frozen until retrospectively updated at the end of the echo period.

FIG. 2 shows in greater detail elements of the apparatus 18 used in performing the method. Ambient audio 10 is converted by the microphone 20 into a signal that is amplified to a usable level by preamplifier 22. The signal is connected to a combiner/switch 30 and to a control input 32 of processing block 24. Also connected to the switch 30 is an algorithmic generator 34 that produces a signal according to an algorithm. Also connected to the switch 30 is a pattern generator 36 that produces a signal according to a stored pattern, which may be an artificially created pattern or a recording of a real audio signal. The switch connects some combination of one or more of the outputs of the preamplifier 22, the algorithmic generator 34, and the pattern generator 36 to a signal input 38 of the processing block 32. The output of the preamplifier 22 controls the processing block 24 via its control input 32 to produce an output signal that is amplified by power amplifier 26 and broadcast by loudspeaker 28. The broadcast audio 16 mixes with audio 12 from the undesirable audio source 14 to form the ambient audio 10.

The output of combiner/switch 30 could therefore include a component from a pseudorandom source (such as that produced by algorithmic generator 34) or from a stored repetitive waveform source (such as that produced by the pattern generator 36). Such sources are well known per se.

If the output of combiner/switch 30 includes incident ambient audio derived from microphone 20, the processing block 24 may act to encourage ambient audio oscillation or may act to prevent ambient audio oscillation. Oscillation will occur if processing block 24 introduces sufficient loop gain. Oscillation may be prevented if processing block 24 ignores input audio while output audio is being broadcast. Then the apparatus may be said to operate in a ‘record-or-replay’ mode, since the processing block 24 gathers incident audio or outputs audio, but never does both simultaneously. Oscillation may also be prevented if processing block 24 uses ‘echo cancellation’ techniques to remove broadcast output audio from an input signal that includes both new incident audio and broadcast output audio. Then the apparatus may be said to operate in a ‘record-while-replay’ mode, since output audio can be broadcast while new incident audio is being gathered. Such ‘echo cancellation’ techniques are well known per se to one skilled in the art, and will not be mentioned further here except to note that such techniques require ‘training’ to learn the characteristics of the path between the output and input of the processing block 24. Such training necessarily requires the production of output audio in the absence of significant new incident audio. This may be done by deliberately producing a specific training signal. Training may be done while processing block 24 executes a ‘record-or-replay’ method. (This training method assumes that output audio is loud enough to dominate new ambient incident audio.) Oscillation may also be prevented when broadcast output audio is constrained to a given bandwidth or bandwidths. Then processing block 24 can use standard filtering techniques to reduce amplitudes in such bandwidths to an acceptable level in signals derived from ambient audio. This is also a ‘record-while-replay’ technique.

Since the control input 32 of the processing block 24 is derived from incident ambient audio, instability will occur if output audio is mistaken for genuinely new ambient audio. Such instability is avoided by applying the ‘record-or-replay’ or ‘record-while-replay’ techniques (described above) to control input 32 of the processing block 24 as well as to the signal input to the processing block 24.

The processing block 24 examines the signal presented at control input 32 so that loud ambient audio and quiet ambient audio may be differentiated and detected. This may be done in many ways, which will be apparent, in the light of this specification, to those skilled in the art of audio processing.

The type of output produced by processing block 24 depends on the presence of loud ambient audio, detected via the signal at control input 32. If loud audio has been detected, the processing block outputs a signal that represents the audio that will obstruct production of ambient audio.

Otherwise, the processing block 24 outputs a signal that represents silence or some other audio that will not obstruct production of ambient audio. An obstructing output signal is produced by processing block 24 from its input signal after the detection of loud ambient audio via control input 32. The combiner/switch 30 and processing block 24 operate to produce an output signal which represents output audio that discourages the production of ambient audio. In tests, interfering with spoken words by broadcasting a shrieking, shrill, oscillatory sound was found to be very assertive and effective, while interrupting speech by reflecting a spoken word (generally at the end of that spoken word) was more polite but less effective. Generally, output audio could be noise, or an alarm sound, a shrieking sound, or a delayed version of undesirable ambient audio, or any other audio that is found to be effective for the desired purpose.

During ‘record-or-replay’ (but not ‘record-while-replay’) operation, when the production of output signal ceases, the processing block 24 rejects the signals at its signal input 38 and its control input 32 for a short time to allow the amplitude of ambient echoes of output audio to decay below the level that overwhelms original ambient audio. The processing block 24 then conditionally accepts larger signals at control input 32 as being caused by new original loud ambient audio provided that the signal is large for longer than a certain time. This time must be shorter than the delay between the detection of loud ambient audio via control input 32 and the decision to create an output signal. The result of such unconditional and conditional rejection is that production of new obstructing audio caused by old output audio is much reduced, if not eliminated. The louder (earlier) loud echoes of output audio are simply ignored. The quieter (later) echoes are rejected if they are not masked by new loud ambient incident audio. Such delays could be simply pre-programmed, or be the result of a detection method that causes such a delay, such as an adaptive detection threshold mechanism for incident audio, which changes its thresholds after the production of an output signal.

If a ‘record-while-replay’ method is unable to reduce the level of broadcast output audio to an acceptable level in signals derived from ambient audio, there is an advantage in combining the ‘record-while-replay’ method with features of the ‘record-or-replay’ method. For example, such a ‘record-while-replay’ method may need to use the ‘record-or-replay’ technique of rejecting input audio after producing output audio, but probably for a shorter time than for a pure ‘record-or-replay’ method.

In both ‘record-or-replay’ and ‘record-while-replay’ modes:

The output signal is processed to maintain a uniformly high mean level of output audio.

A minimum amount of incident loud audio is detected at control input 32 of the processing block before processing block 24 produces output audio. Otherwise, the incident loud audio is rejected. This is to eliminate activation by spurious bursts of noise. Preferably bursts of noise that are less than a typical short spoken word are rejected.

A first mode of operation of the arrangement shown in FIG. 2 ‘interferes’ with spoken words, preferably before they have finished. In such a first mode, processing block 24 outputs interfering audio before the end of that loud ambient audio, in order to interfere with the loud ambient audio. A delay between detection of loud ambient audio and output of an interfering signal is necessary to enable the processing block 24 to reject signals at control input 32 that arise from bursts of ambient noise, as explained previously. The delay is also necessary if the output audio is to contain a delayed copy of input audio, since time is required to gather that input audio. The delay may also be necessary to enable detection of loud ambient audio via control input 32 (depending on the method used). The delay may also be necessary to enable determination of the characteristics of the control signal that indicate loudness and quietness. The delay may also be necessary to determine the recent peak amplitudes of the input signal to the processing block 24, which may be temporarily stored for future use in automatic-gain-control. If the ‘record-or-replay’ method is in use, the delay may also be necessary to reject unwanted echoes of previous output audio, as explained previously.

The action of the processing block 24 when producing an interfering output signal is to amplify its input signal into an output signal that produces output audio with consistently loud mean output amplitude. If the output signal of the combiner/switch 30 is independent of the preamplifier 22, the output signal from the processing block 24 is simply amplified. If the output signal of the combiner/switch 30 is dependent on the preamplifier 22, the output signal from the processing block 24 is adjusted according to stored peak amplitudes of the signal input and new peak amplitudes of the signal input. Methods of applying automatic-gain-control will be apparent, in the light of this specification, to those skilled in the art of audio processing. Preferably the interfering output signal does not overdrive the power amplifier 26 or the loudspeaker 28. Once production of an output signal from processing block 24 has started, it continues for a preset time, or until original incident undesired audio is quiet. In ‘record-or-replay’ mode, while the processing block 24 is producing an interfering output signal, the processing block 24 assumes that it cannot differentiate between signals at its control input 32 that were caused by original ambient audio and those that were caused by output audio. So the processing block 24 freezes detailed interpretation of its control input 32. The processing block 24 also freezes detailed interpretation of its signal input 38, except as previously noted when preamplifier 22 contributes to the signal source.

A second mode of operation of the arrangement shown in FIG. 2 ‘interrupts’ speech during gaps in that speech. In such a second mode, processing block 24 starts the output of interrupting audio just after a break in the incident undesired audio. If the combiner/switch 30 is operated to produce its output from the preamplifier 22, this second mode reflects essentially whole spoken words back to a speaker, either almost immediately after that word was finished, or a short time later.

Processing block 24 acts to prevent oscillation by applying either the ‘record-or-replay’ or ‘record-while-replay’ methods described above to both its signal input 38 and its control input 32, to isolate genuinely new ambient audio.

If the processing block 24 is executing the ‘record-or-replay’ method, stability is achieved simply by the act of ignoring input signals while producing interrupting output audio. If the combiner/switch 30 is operated to produce its output from the preamplifier 22, the overall effect is that processing block 24 detects new loud ambient audio, stores that audio until it becomes quiet, replays that stored audio and simultaneously ignores ambient audio, and then returns to searching for new loud ambient audio.

If the processing block 24 is executing the ‘record-while-replay’ method, stability is achieved by removing the output signal from input signals. If the combiner/switch 30 is operated to produce its output from the preamplifier 22, the processing block 24 isolates new ambient audio from its input signal and stores it in temporary memory. The processing block 24 isolates new ambient audio at its control input 32 and detects the start of new loud ambient audio. When new isolated quiet ambient audio is detected via control input 32 after new isolated loud ambient audio, the processing block 24 outputs the stored input signal from temporary memory, from the start of the new isolated loud ambient audio to the start of the new isolated quiet ambient audio.

If the combiner/switch 30 is operated to produce its output from the preamplifier 22, both ‘record-or-replay’ and ‘record-while-replay’ methods cause processing block 24 to automatically start replay of stored audio when a preset maximum amount of audio has been stored. This is to eliminate lockup in the presence of continuously loud new ambient audio.

There are many variations on the methods described above. They could be used on their own, or could be combined with other known or obvious methods. For example, if audio is quiet for a period and then loud audio is detected, or ambient audio has been predominantly quiet for a period or for a predetermined number of cycles of broadcast output, the method of delaying whole spoken words could be used. Otherwise, if there appears to be a substantial amount of loud audio, an interfering method could be used. This has the overall effect of interrupting a speaker if there is a small amount of loud ambient audio present, and interfering with speech if there is a large amount of loud ambient audio present. This combined method is useful because interrupting is a modest form of assertion and sufficient to dissuade some but not all individuals from speaking, while interfering is a more robust form of assertion, and dissuades more individuals from speaking. Using this algorithm, the method will continue interrupting if interruption is effective. Otherwise, it will use interference.

Another variation is to activate the method depending of the time of day, the relative occurrence of loud ambient audio, and so on.

Another variation is to add at least one sensor that detects desirable audio. The detection of loud audio at that sensor takes precedence over the detection of undesired audio and causes desired audio to be broadcast from a, or the, loudspeaker instead of obstructing audio. Normally such desirable audio will be localised audio, such as words spoken directly into a microphone, instead of ambient audio. This is because it must be possible to distinguish desired audio from undesired ambient audio. It is, however, possible for desired audio to originate at a distant source. Its general form is illustrated in FIG. 3, where an audio sensor 40 produces an input signal from ambient desired audio 42 and another audio sensor 20 produces an input signal from ambient undesired audio 10. A loudspeaker 28 is driven by the output of decision circuit 44. Obstructer circuit 46 produces an obstructing signal using one of the methods previously described. The overall principal of the variation is that decision circuit 44 outputs a signal derived from audio sensor 40 when desired audio is active, and otherwise outputs an obstructing signal from obstructer circuit 46. The output signal is subtracted from the desired input and also from the undesired input using subtractors 48,50, such that any trace of the output signal is at an acceptably low level. It may also be necessary to remove the clean desired signal from the clean undesired signal using a subtractor 52, such that any trace of the clean allowed signal is at an acceptably low level.

The general case may be simplified in several ways, including:

If the ‘record-or-replay’ method is in use, there is no need to subtract output audio from undesired input audio. This eliminates subtractor 50.

In the special case where the desired audio 42 comes from a significantly different direction to undesired audio 12, the use of a directional microphone 20 pointed towards the undesired audio 12 will pick up the undesired audio 12 but not the desired audio 42, thus eliminating the stage of removing the desired signal from the undesired signal. This eliminates subtractor 52.

In the special case where the output audio 16 comes from a significantly different direction to the desired input or the undesired input, the use of directional microphones 20,40 pointed away from the output audio 16 will not pickup the output signal, thus eliminating the stage of removing the output signal from the desired signal and from the undesired signal. This eliminates subtractors 48,50.

In the special case where the desired signal is produced using a non-audio transducer 40, such as throat microphone, the desired signal will not include the output signal, thus eliminating the stage of removing output audio from desired audio. This eliminates subtractor 48.

In the special case where desired audio 42 is much louder than undesired audio 12, the amplitude of input audio from a single sensor can be compared to a threshold, and input audio processed as desired audio when above that threshold, or processed as undesired audio when below that threshold.

FIG. 4 illustrates the preferred physical architecture of an apparatus for performing the methods described above. An electret microphone-insert 20 converts ambient audio into an electrical signal that is magnified by amplifiers 22a (such as the National Semiconductor LM358 set for a gain of 2) and 22b (such as the National Semiconductor LM386 bypassed for maximum gain). The output of amplifier 22b is the audio input to a codec 54 (such as the Texas Instruments TCM320AC36). The codec 54 is driven by control signals generated by a microcontroller 56 (such as a Microchip PIC16C64). The codec 54 converts the incident analogue audio to digital and compresses it to an 8 bit word (using μlaw coding in this example).

The microcontroller 56 controls the codec 54 via reset, data, clock and sync signals 58 such that the codec 54 sends the compressed data to the microcontroller 56, and performs manipulation of the data according to the program stored inside the microcontroller 56. The microcontroller 56 has insufficient internal temporary memory, and therefore uses RAM 60 (8k×8 industry standard type 6264) to store the compressed data samples. The microcontroller 56 produces address signals 62 and control signals 64 to drive the RAM 60. The microcontroller 56 exchanges data with the RAM 60 via data signals 66. When the microcontroller 56 has finished its processing, it sends a compressed digital version of the output audio to the codec 54 using signals 58. The codec 54 converts the digital data to an analogue waveform that is amplified by the power amplifier 26 (such as Analog Devices SSM2211), that drives the loudspeaker 28 (such as a 1.5W loudspeaker).

The microcontroller 56 derives its timebase from a crystal 68 (preferably 20 MHz). The crystal 68 also drives a counter 70 (such as the industry standard HC4024) that produces a reference clock 72 for the codec 54.

If the method involves the storage of ambient audio, the microcontroller 56 continually drives the RAM 60 so that compressed input data is continually written to the RAM 60. New data overwrites the oldest data when the RAM 60 is full. The microcontroller 56 is also continually inspecting input data to detect contiguous loud audio. There are many ways of determining when loud audio is present, all of which will be apparent, in the light of this specification, to one skilled in the art. In a prototype, time was divided into arbitrary contiguous intervals of 20 ms or so, the peak value in each interval was noted, and the last nine peak values recorded in a FIFO. An upper threshold is set to an appropriate proportion, such as a half, or more preferably a quarter, of the median value in the peak FIFO. When the input amplitude exceeds the upper threshold, a 20 ms or so retriggerable ‘upper-monostable’ is set. A lower threshold is set to an appropriate proportion, such as an eighth, or more preferably a sixteenth, of the median value in the peak FIFO. When the input amplitude exceeds the lower threshold, a 20 ms or so retriggerable ‘lower-monostable’ is set. If the prototype's state is ‘audio absent’, the state changes to ‘audio present’ when the ‘upper-monostable’ is active. If the prototype's state is ‘audio present’, the state remains as ‘audio present’ as long as the ‘lower-monostable’ is active. The actual start of contiguous audio is taken to be 20 ms or so before the state changes to ‘audio present’. The actual end of contiguous audio is taken to be 20 ms or so after the state changed to ‘audio absent’, when the state has been ‘audio absent’ for 80 ms or so. It will be appreciated that this is just one method of determining the presence or absence of spoken words, that the values quoted here can be varied, and that there are other methods.

FIG. 5 is an illustration of a state-machine that is implemented as a program in the microcontroller 56 in the preferred implementation. The program in the microcontroller 56 examines the samples representing incident ambient audio.

In FIG. 5, new loud incident ambient audio is examined for loud audio during the QUIESCENT state 74, and the characteristics of quiet audio are updated. When loud audio is detected, the state changes.

If the program spends more than a short time T1 (120 ms in the prototype) in the QUIESCENT state 74, the program executes the interrupting method 76, where entire spoken words are replayed as soon as they have finished. Then the program returns to the QUIESCENT state 74. On the other hand, if the program spends less than that short time T1 in the QUIESCENT state 74, the program executes the interfering method 78 and then returns to the QUIESCENT state 74.

With the interfering method 78, from the QUIESCENT state 74, the state changes to GATHER1 state 80. In GATHER1 state 80, the amplitude of detected audio is examined so as to temporarily record the peak levels of the audio, and the characteristics of loud audio are updated. If audio becomes quiet, the state changes from the GATHER1 state 80 to TEST1 state 82.

In TEST1 state 82, the time since the broadcast of output audio is measured, and the duration of the loud audio is examined. If the time since broadcast of output audio is less than a predetermined time T2 (the prototype used a duration of 140 ms), or the duration of the loud audio is less than a predetermined time T3 (the prototype used a duration of 180 ms), the audio is rejected and the state returns to the QUIESCENT state 74. (If in a specific instance, T2 is less than T3, then obviously the test using T2 is redundant.) Otherwise, the state changes to OUTPUT1 state 84.

In GATHER1 state 80, if the time spent reaches a limit T4 (the prototype used a duration of 180 ms), the state changes to OUTPUT1 state 84.

In the OUTPUT1 state 84, audio is generated from a signal, and is broadcast. When the time spent in OUTPUT1 state 84 reaches a limit T5 (the prototype used a duration of 180 ms), the state changes to ECHO1 state 86.

In the ECHO1 state 86, all ambient audio is ignored. When the time spent in ECHO1 state 86 reaches a limit T6 (the prototype used a duration of 20 ms), the state returns to QUIESCENT state 76.

The preferred implementation uses incident audio as the signal that is converted to audio and broadcast. The audio sample that has just been gathered is amplified by an automatic gain control to produce a consistently loud mean output amplitude without clipping. The microcontroller does this by noting the maximum sample amplitude during the GATHER1 state 80, and amplifying all samples by the same amount so that the maximum sample amplitude during replay is the peak desired value. If feedback causes larger input samples that would be clipped by this process, the amount of amplification is reduced so as to avoid clipping.

An alternative implementation could use a signal derived from an algorithmic generator. One example is the use of a pseudo-random generator to produce apparently random noise. (A description of pseudo-random generators is in ‘Pseudo Random Sequences and Arrays’—MacWilliams and Sloane, proc. IEEE vol. 64 #12, December 1976.) A suitable polynomial is [x¹⁵+x+1], since it has few taps but has a cycle length of a few seconds when incremented once per sample period. The contents of the generator could be repeatedly exclusive-ORed with audio samples during the start of the GATHER1 state 80 to provide a variable start position when the time comes to provide output audio, provided that steps are taken to detect the all-zero lockup state and exit it. An audio sample could be produced from the generator by incrementing it every sample period. The six least significant bits of the generator are used to produce a varying audio output. Four bits are used as the amplitude part of a μlaw sample, another bit as the least significant bit of the segment value of that sample, and another bit as the sign bit. The two most significant bits in the segment value should be set to 1, to ensure a large amplitude output. This produces ‘white’ noise audio, which may be acceptable for interrupting certain speakers.

Another alternative implementation could use a signal derived from a primitive pattern stored in non-volatile memory. At each sample period, a successive value of the pattern is converted to audio. When the end of the pattern is reached, the method cycles back to using the start of the pattern, and the process repeats. Such patterns (such as sine wave, or more complex cyclic signals) may be generated by algorithms, while others (such as a stored version of actual positive audio feedback) may be stored versions of actual audio signals.

With the interrupting method 76 (where entire spoken words are replayed as soon as they have finished), from the QUIESCENT state 74, the state changes to GATHER2 state 88. In GATHER2 state 88, the amplitude of detected audio is examined so as to temporarily record the peak levels of the audio, the characteristics of loud audio are updated, and detected audio is temporarily stored. If audio becomes quiet, the state changes from GATHER2 state 88 to TEST2 state 90.

In TEST2 state 90, the time since the broadcast of output audio is measured, and the duration of the loud audio is examined. If the time since broadcast of output audio is less than a predetermined time T7 (the prototype used a duration of 140 ms), or the duration of the loud audio is less than a predetermined time T8 (the prototype used a duration of 180 ms), the audio is rejected and the state returns to QUIESCENT state 74. (If in a specific instance, T7 is less than T8, then obviously the test using T7 is redundant.) Otherwise, the state changes to OUTPUT2 state 92.

In GATHER2 state 88, if the time spent reaches a limit T9 (the prototype used a duration of 400 ms), the state changes to OUTPUT2 state 92.

In the OUTPUT2 state 92, audio is replayed from the store, automatic-gain-control is applied and audio is broadcast. When the store is empty, the state changes to ECHO2 state 94.

In the ECHO2 state 94, all ambient audio is ignored. When the time spent in ECHO2 state 94 reaches a limit T10 (the prototype used a duration of 20 ms), the state returns to QUIESCENT state 74.

FIG. 6 illustrates the processing of input parameters such as agc settings and threshold level settings. In QUIESCENT3 state 95, input parameters are adjusted according to the level of the received ambient audio. If the apparatus enters an OUTPUT1 state 84 or OUTPUT2 state 92, the parameter processing enters OUTPUT3 state 96 and stays there until the apparatus leaves OUTPUT1 state 84 or OUTPUT2 state 92. During OUTPUT3 state 96, input parameters are not changed. If the apparatus enters an ECHO1 state 86 or ECHO2 state 94, the parameter processing enters ECHO3 state 97 and stays there until the apparatus leaves ECHO1 state 86 or ECHO2 state 94. During ECHO3 state 97, input parameters are not changed.

One implementation may then follow path-a, while it may be that another implementation will follow path-b.

In path-a, the parameter processing enters CONDITIONAL4 state 101, during which input parameters are not changed but pending changes due to the level of the received ambient audio are noted. After a time T11 (the prototype used a duration of 140 ms) in CONDITIONAL4 state 101, OBSERVE4 stage 102 observes whether ambient audio is loud, or is loud and has recently been loud. If loud ambient audio is present, the pending changes are applied to the input parameters in ROLL_FORWARD state 103, and the apparatus then returns to QUIESCENT3 state 95. If no new ambient audio is present, the pending changes are abandoned and the apparatus returns directly to QUIESCENT3 state 95.

In path-b, the parameter processing enters CONDITIONAL5 state 98, during which input parameters are adjusted according to the level of the received ambient audio but those changes are temporarily recorded. After a time T12 (the prototype used a duration of 14 ms) in CONDITIONAL5 state 98, OBSERVE5 stage 99 observes whether ambient audio is loud, or is loud and has recently been loud. If loud ambient audio is present, the apparatus returns directly to QUIESCENT3 state 95. If no new ambient audio is present, the changes are removed from the input parameters in ROLL_BACK state 100, and the apparatus then returns to QUIESCENT3 state 95.

It should be noted that the embodiments of the invention have been described above purely by way of example and that many modifications and developments may be made thereto within the scope of the present invention. For example, if the obstructing audio is to be a shrieking oscillatory noise, the processing block 206 need merely activate and deactivate a common buzzer, and combiner/switch 205 is redundant. Many such buzzers are much more efficient than a loudspeaker at converting electricity into sound, and may produce much more directional sound than a loudspeaker. These properties may be useful in portable equipment, for example. Also, this means that RAM 60, power amplifier 26, and loudspeaker 28 are redundant. It may also be feasible to replace the codec 54 with pure analogue circuitry that derives the amplitude of incoming audio, its mean peak value, various thresholds, and the size of incoming audio relative to those thresholds. The amplitude can be derived using a rectifier circuit. The mean peak value (rather than the median value used for simplicity in the microcontroller implementation) can be derived by peak-detecting and filtering the rectified audio. The mean peak value can be divided to produce a high threshold and a low threshold. A silence threshold can be derived from a fixed voltage. These thresholds can be compared with rectified data using comparators. The outputs of the comparators can be sampled by a microcontroller, which implements the rest of the algorithm and drives a buzzer when appropriate. The microcontroller produces timing waveforms that cause the mean peak circuitry to accept and ignore and conditionally accept or roll-back incoming audio. One convenient method is to use duplicate low pass filters, each filtering the peak-detected signal. The input to the first duplicated filter is enabled only during the period when quiet echoes of output audio are present. The input to the second duplicate filter is disabled at certain times, depending on the desired effect, and the output of the first filter is added or subtracted to the output of the second filter as required. The resultant signal is the mean peak value.

1. An audio processing method, for example for discouraging vocalisation or the production of complex sounds, the method comprising the steps, performed in a repeating cycle, of: receiving (74) ambient audio; detecting (74) when the received ambient audio is loud; and broadcasting (84,92) a burst of output audio so as to mix with the ambient audio, the burst of output audio being timed in dependence upon the detection of loud ambient audio.

2. A method as claimed in claim 1, further comprising the step, in each cycle, of deciding (80,82,88,90) whether or not to perform the broadcasting step in dependence upon at least one parameter related to the received ambient audio and/or the broadcast output audio.

3. A method as claimed in claim 2, wherein, in the deciding step, the decision is made in dependence upon the length of time for which the received ambient audio is loud.

4. A method as claimed in claim 3, wherein the decision is made not to perform the broadcasting step if the received ambient audio is loud for less than a first predetermined period of time (T3,T8).

5. A method as claimed in any of claims 2 to 4, wherein, in the deciding step, the decision is made in dependence upon the length of time since the preceding broadcast of such a burst of output audio.

6. A method as claimed in claim 5, wherein the decision is made not to perform the broadcasting step if the length of time since the preceding broadcast of such a burst of output audio is less than a second predetermined period of time (T2,T7).

7. A method as claimed in claim 6, when dependent indirectly on claim 4, wherein the decision is made to perform the broadcasting step if the received ambient audio is loud for more than said first predetermined period of time (T3,T8) and the length of time since the preceding broadcast of such a burst of output audio is more than said second predetermined period of time (T2,T7).

8. A method as claimed in any of claims 2 to 7, wherein the decision is made to perform the broadcasting step if the received ambient audio is loud for more than a third predetermined period of time (T4,T9).

9. A method as claimed in any preceding claim, further comprising the step (86,94) of ignoring (86,94) any detection of loud ambient audio for a period of time (T6,T10) after the broadcasting step.

10. A method as claimed in claim 9, wherein the period of time during which any such detection is ignored is a fourth predetermined period of time (T6,T10).

11. A method as claimed in any preceding claim, wherein, in each cycle, there is a delay (T3 to T4, T8 to T9) between the time when the ambient audio is detected as loud and the time when the broadcasting step is commenced.

12. A method as claimed in claim 11, wherein, in the case where the ambient audio is detected as loud for less than a fifth predetermined period of time (T4,T9), the broadcasting step is commenced substantially immediately that the ambient audio ceases to be detected as loud.

13. A method as claimed in claim 11 or 12, wherein, in the case where the ambient audio is detected as loud for said fifth predetermined period of time (T4,T9), the broadcasting step is commenced substantially immediately at the end of said fifth predetermined period of time.

14. A method as claimed in any preceding claim, further comprising the step of making one of the following decisions (74):
whether or not the received incident audio is loud at substantially the beginning of each cycle;
whether or not incident audio has been predominantly loud for a given time; or
whether or not a predetermined number of output cycles have already occurred,
and selecting between a first mode (78) of operation if it is, and a second mode (76) of operation if it is not.

15. A method as claimed in claim 14, wherein the period of time for which the output audio is broadcast is determined differently in the two modes.

16. A method as claimed in claim 14 or 15, when dependent directly or indirectly on claim 8, wherein said fifth predetermined period of time (T4) in the first mode is different to said fifth predetermined period of time (T9) in the second mode.

17. A method as claimed in any of claims 14 to 16, when dependent directly or indirectly on any of claims 11 to 13, wherein the delay is determined differently in the two modes.

18. A method as claimed in any preceding claim, further comprising the step, in each cycle, of generating (84,92) the output audio at least in part from the received ambient audio.

19. A method as claimed in claim 18, further comprising the step of automatically controlling the level of the output audio.

20. A method as claimed in claim 19, wherein the controlling step comprises the step of detecting the level of the received audio, and applying a gain in generating the output audio dependent on the detected level so that the peak level of each burst of output audio is substantially predetermined.

21. A method as claimed in claim 20, wherein, in the level detecting step, the level of the received audio is ignored while each broadcasting step is being performed.

22. A method as claimed in claim 21, wherein, in the level detecting step, the level of the received audio is ignored for a period of time immediately after each broadcasting step has been performed.

23. A method as claimed in any of claims 18 to 22, wherein the content of the output audio is produced at least in part from the substantially current content of the received ambient audio.

24. A method as claimed in any of claims 18 to 22, wherein the content of the output audio is produced at least in part from delayed content of the received ambient audio.

25. A method as claimed in any preceding claim, wherein the content of the output audio is produced at least in part from a source independent of the incident ambient audio.

26. A method as claimed in any preceding claim, wherein the step of detecting loud ambient audio comprises comparing the level of the received audio with at least one threshold.

27. A method as claimed in claim 26, further comprising the step of automatically adjusting the threshold, or at least one of the thresholds, in dependence upon an average value of the level of the received ambient audio.

28. A method as claimed in claim 27, wherein adjustment of the threshold(s) is independent of the level of the received ambient audio while each broadcasting step is being performed.

29. A method as claimed in claim 28, wherein, adjustment of the threshold(s) is independent of the level of the received ambient audio for a period of time immediately after each broadcasting step has been performed.

30. An audio processing apparatus adapted to perform the method of any preceding claim.
